(19) United States
(12) Patent Application Publication
(10) Pub. No.: US 2012/0266931 A1
(43) Pub. Date: Oct. 25, 2012

(54) SOLAR COLLECTION DEVICE

(75) Inventor: MENG-CHE YU, Tu-Cheng (TW)

(73) Assignee: HON HAI PRECISION INDUSTRY CO., LTD., Tu-Cheng (TW)

(21) Appl. No.: 13/158,469

(22) Filed: Jun. 13, 2011

(30) Foreign Application Priority Data
Apr. 22, 2011 (TW) 100113958

(51) Int. Cl. H01L 31/042

(52) U.S. Cl. 136/244

(57) ABSTRACT

A solar collection device includes a circular bottom wall; a peripheral sidewall, and a flexible solar cell panel. The peripheral sidewall is extending from a periphery of the bottom wall. The bottom wall and the sidewall cooperatively form a bucket. The bucket includes an opening. The area of the opening is two to three times the area of the bottom wall. The flexible solar cell panel is attached over an entire interior surface of the sidewall in the bucket.

### BACKGROUND

1. Technical Field

The present disclosure relates to solar collection devices.

2. Description of Related Art

At present, solar panels are mostly flat. Energy collection is inefficient, because solar rays are readily reflected by these flat solar panels. Some means of redirecting or condensing these solar rays is required but this cannot be done usefully or expediently to flat solar panels.

What is needed, therefore, is a more effective solar collection device which has simple structure and is easy to install.

### BRIEF DESCRIPTION OF THE DRAWINGS

Many aspects of the present solar collection device can be better understood with reference to the following drawings. The components in the drawings are not necessarily drawn to scale, the emphasis instead being placed upon clearly illustrating the principles of the present solar collection device. Moreover, in the drawings, like reference numerals designate corresponding parts throughout the views.

FIG. 1 shows a perspective view of a solar collection device according to a first embodiment of the present disclosure.

FIG. 2 is a cross-sectional view of the solar collection device shown in FIG. 1, taken along line II-II.

FIG. 3 is a cross-sectional view of a solar collection device according to a second embodiment of the present disclosure.

### DETAILED DESCRIPTION

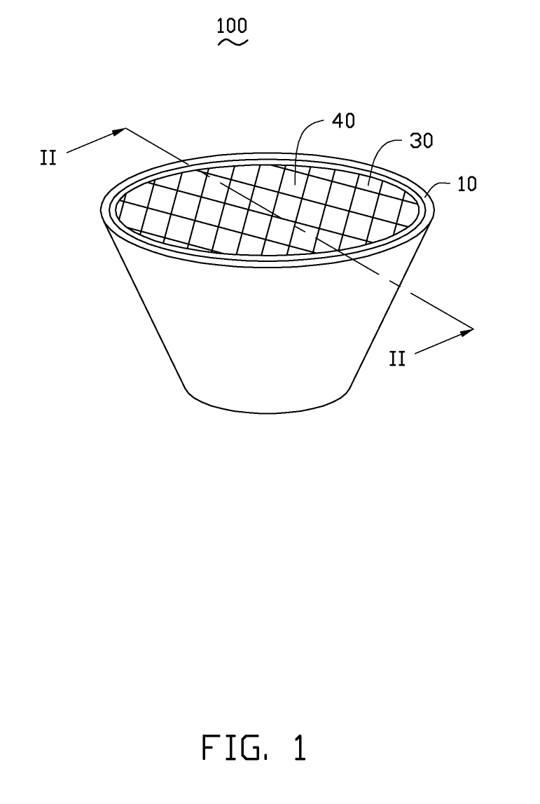

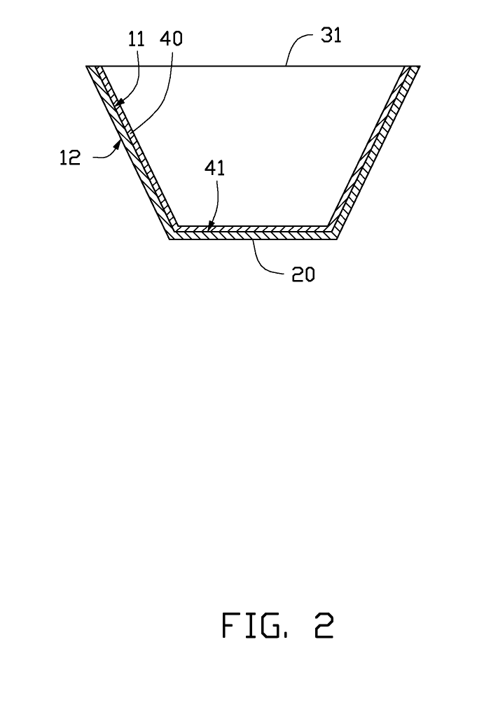

Referring to FIGS. 1 and 2, a solar collection device 100 includes a sidewall 10 and a bottom wall 20. The bottom wall 20 is flat and circular. The sidewall 10 is extending from a periphery of the bottom wall 20. The bottom wall 20 and the sidewall 10 cooperatively form a bucket 30 with a circular opening 31 at the top. The sidewall 10 is slanted outwardly relative to the bottom wall 20. The bottom wall 20 and the opening 31 are coaxial.

In general, the larger the area of the top opening 31, the more solar energy which is collected. The area of the opening 31 is two to three time the area of the entire interior surface of the sidewall 10 in the bucket 30. The height of the solar collection device 100 in the range from 20 cm to 30 cm. This solar collection device 100 is capable of collecting much more solar energy than conventional flat solar panels. The height of solar collection device 100 must be sufficient to sink/to gather a large proportion solar rays.

The sidewall 10 has an interior surface 11 and an outer surface 12. A flexible solar cell panel 40 is attached to and molds itself to the shape of the interior surface 11. The solar cell panel 40 includes a flexible substrate and a photoelectric conversion layer on the flexible substrate. Adhesive may be used to attach the solar cell panel 40 to the interior surface 11. Another solar cell panel 41, rigid or flexible, may be attached to or just placed on the inside of the bottom wall 20. If the solar cell panel 41 is flexible, the solar cell panels 40 and 41 may be a single solar panel. If no solar cell panel is placed on the bottom wall 20, solar rays reflected by the bottom wall 20 (or indeed by the solar cell panel 41 itself if it is in place) may be absorbed by the solar cell panel 40 and efficient utilization of solar rays is increased.

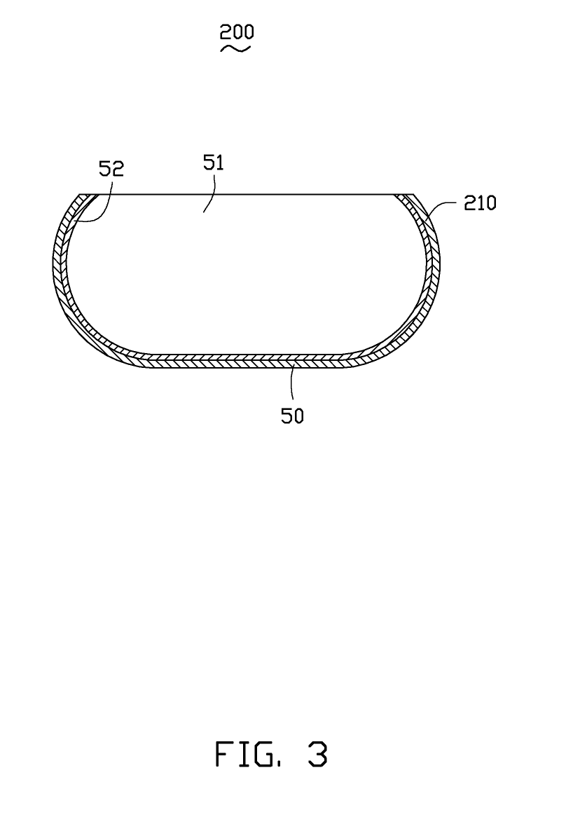

Referring to FIG. 3, an alternative configuration of a solar collection device 200 differs from the solar collection device 100 by including an outwardly curved sidewall 210. More solar rays may be condensed and retained into the solar collection device 200 due to the sidewall 210. The flat bottom wall 50 abuts against the base of the sidewall 210. The flat bottom wall 50 is circular or square, and the top opening 51 has a corresponding shape. A flexible solar cell panel 52 is attached to the interior surface of the sidewall 210 and to the flat bottom wall 50.

In the embodiment, known methods and means can be employed to store and make use of the solar power generated by the solar cell panel 40 (or 41, 52). A number of solar collection devices 100 (or 200) can be connected in series to increase the generating capacity. The solar collection devices are capable of collecting solar energy reflected by its bottom wall to increase utilization of the solar rays, and no other concentration devices need to be installed.

It is understood that the above-described embodiments are intended to illustrate rather than limit the disclosure. Variations may be made to the embodiments without departing from the spirit of the disclosure. Accordingly, it is appropriate that the appended claims be construed broadly and in a manner consistent with the scope of the disclosure.

What is claimed is:

1. A solar collection device, comprising:
a circular bottom wall;
a peripheral sidewall extending from a periphery of the bottom wall; the bottom wall and the sidewall cooperatively forming a bucket, the bucket comprising an opening, wherein the area of the opening is two to three times the area of the bottom wall; and
a flexible solar cell panel attached over an entire interior surface of the sidewall in the bucket.

2. The solar collection device of claim 1, wherein a height of the bucket is in a range from 20 cm to 30 cm.

3. The solar collection device of claim 1, wherein the sidewall is slanted outwardly relative to the bottom wall.

4. The solar collection device of claim 1, wherein the sidewall is outwardly curved.

5. The solar collection device of claim 1, further comprising a flexible solar cell panel attached on the bottom wall in the bucket.

6. The solar collection device of claim 1, further comprising a rigid solar cell panel placed on the bottom wall in the bucket.
